(19) United States
(12) Patent Application Publication
(10) Pub. No.: US 2026/0076146 A1
(43) Pub. Date: Mar. 12, 2026

(54) APPARATUS FOR PROCESSING SUPERCRITICAL SUBSTRATE

(71) Applicant: KCTECH CO., LTD., Anseong-si (KR)

(72) Inventors: Hyung-Chul KIM, Gyeonggi-do (KR); You-Sun Jung, Gyeonggi-do (KR)

(21) Appl. No.: 19/297,566

(22) Filed: Aug. 12, 2025

(30) Foreign Application Priority Data
Sep. 6, 2024 (KR) 10-2024-0121948

(51) Int. Cl. H01L 21/677; H01L 21/02; H01L 21/67

(52) U.S. Cl. CPC H10P 72/3411; H10P 72/0408; H10P 72/0606; H10P 72/3406; H10P 70/80

(57) ABSTRACT

The present invention relates to an apparatus for processing supercritical substrate comprising: a chamber having a processing space; a substrate supporting unit for supporting a substrate; an opening/closing unit for opening or closing the processing space; a loading/unloading unit for loading a substrate into or unloading the substrate from the substrate supporting unit; a detection unit for detecting the loading/unloading unit or the substrate; and a control unit for controlling the opening/closing unit, wherein the control unit controls the operation of the opening/closing unit in response to the detection unit detecting the loading/unloading unit or the substrate.

### CROSS-REFERENCE TO RELATED APPLICATIONS

This application claims the benefit of priority of the Korean Patent Application No. 10-2024-0121948 filed on Sep. 6, 2024, which is hereby incorporated by reference as if fully set forth herein.

### FIELD

This present application is about an apparatus for processing supercritical substrate, more specifically, an apparatus for processing a substrate using a supercritical fluid.

### BACKGROUND

In general, semiconductors are produced through processing processes such as a deposition process of depositing a thin film of a specific material on a substrate, a photo process of selectively exposing the thin film using a photosensitive material, and an etching process of forming a pattern by selectively removing the thin film in the exposed portion. In this case, impurities such as metals, particles, and organic materials generated during the processing process have an important influence on the yield and quality of the semiconductor. Thus, the substrate is subjected to a cleaning process and a drying process for removing impurities.

Here, an apparatus for processing supercritical substrate performs the drying process on the substrate on which the cleaning process has been completed. The drying process dries the cleaning liquid on the substrate on which the cleaning process has been completed. The apparatus for processing supercritical substrate may dry the drying prevention solution applied to the substrate in the cleaning process by spraying a drying fluid in a supercritical state onto the substrate. In this case, the apparatus for processing supercritical substrate needs to maintain the interior of the chamber at high temperature and high pressure to maintain the drying fluid in the supercritical state.

FIG. 1 is a schematic cross-sectional view of an apparatus for processing supercritical substrate according to the prior art.

The apparatus for processing supercritical substrate 100 according to the prior art may include a chamber 110 provided with a processing space 110S for processing the substrate 200, a substrate supporting unit 120 supporting substrate 200, an opening/closing unit 130 for opening or closing the processing space 110S, and a loading/unloading unit 140 for carrying the substrate 200 onto or out of the substrate supporting unit 120. Here, the apparatus for processing supercritical substrate 100 according to the prior art may maintain the processing space 110S in a high-temperature and high-pressure state in order to process the substrate 200 by the supercritical fluid. For this reason, the apparatus for processing supercritical substrate 100 according to the prior art has a problem in that a detection unit for detecting the substrate 200 or the loading/unloading unit 140 cannot be installed inside the chamber 110. Therefore, in the apparatus for processing supercritical substrate 100 according to the prior art, loading/unloading unit 140 or the substrate 200 collide with each other due to the malfunction of the opening/closing unit 130. For example, in the apparatus for processing supercritical substrate 100 according to the prior art, as the opening/closing unit 130 malfunctions, a collision may occur with the loading/unloading unit 140 or the substrate 200. Therefore, in the apparatus for processing supercritical substrate 100 according to the prior art, a problem in which the loading/unloading unit 140 or the substrate 200 is damaged frequently occurred.

### SUMMARY

An embodiment of the present application is to provide an apparatus for processing supercritical substrate capable of preventing collisions between opening/closing unit and a loading/unloading unit or a substrate.

In addition to the objects of the present disclosure as mentioned above, additional objects and features of the present disclosure will be clearly understood by those skilled in the art from the following description of the present disclosure.

One embodiment of the present application to achieve the above technical problem provide an apparatus for processing supercritical substrate comprising: a chamber having a processing space; a substrate supporting unit for supporting a substrate; an opening/closing unit for opening or closing the processing space; a loading/unloading unit for loading a substrate onto or unloading the substrate from the substrate supporting unit; a detection unit for detecting the loading/unloading unit or the substrate; and a control unit for controlling the opening/closing unit. Wherein the control unit controls the operation of the opening/closing unit in response to the detection unit detecting the loading/unloading unit or the substrate.

The present invention can be implemented so that the control unit operates the opening/closing unit based on the result of the detection unit detecting the loading/unloading unit or the substrate. Accordingly, the present invention can prevent the loading/unloading unit or the substrate and the opening/closing unit from being operated simultaneously by the detection unit detecting the operation of the loading/unloading unit or the substrate. Accordingly, the present invention can prevent the opening/closing unit and the loading/unloading unit or the substrate from colliding with each other due to the simultaneous operation of the loading/unloading unit or the substrate, thereby preventing damage to the loading/unloading unit or the substrate.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a cross-sectional view of an apparatus for processing supercritical substrate according to the prior art.

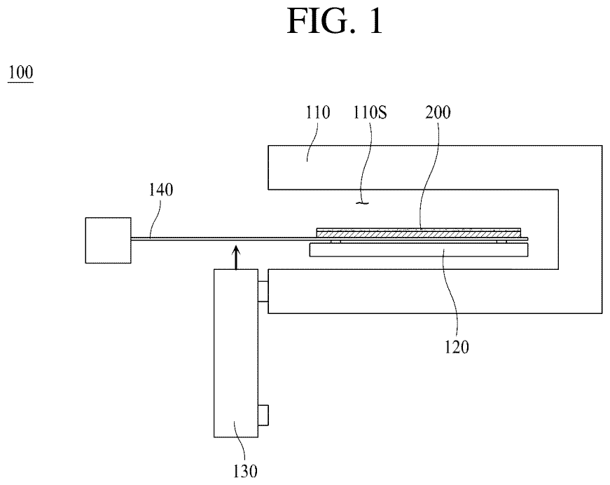

FIG. 2 is a schematic cross-sectional view of an apparatus for processing supercritical substrate according to the present invention.

FIG. 3 is a schematic cross-sectional view of the apparatus for processing supercritical substrate according to the present invention, before loading the substrate.

FIG. 4 is a schematic cross-sectional view of the apparatus for processing supercritical substrate according to the present invention, with the loading/unloading unit entered to load the substrate.

FIG. 5 is a schematic cross-sectional view of the apparatus for processing supercritical substrate according to the present invention, with the loading/unloading unit retracted after the substrate has been loaded.

FIG. 6 is a schematic cross-sectional view of the apparatus for processing supercritical substrate according to the present invention, with the processing space closed after the substrate has been loaded.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just”or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

Hereinafter, an embodiment of the apparatus for processing supercritical substrate according to the present invention will be described in detail with reference to the attached drawings.

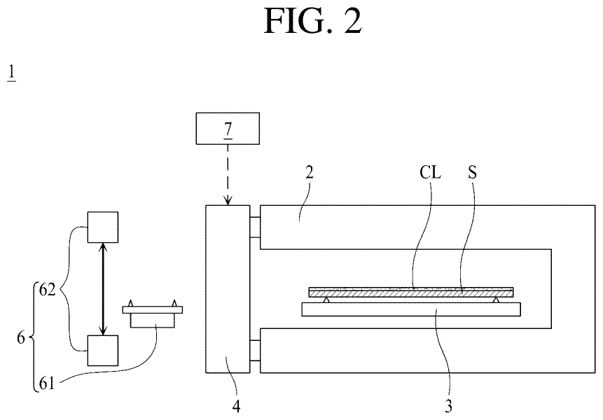

Referring to FIG. 2, the apparatus 1 for processing supercritical substrate according to the present invention performs a processing process on a substrate S. The substrate S may be a silicon substrate, a glass substrate, a metal substrate, or the like. The apparatus 1 for processing supercritical substrate according to the present invention may perform a drying process for drying the substrate S. According to the present invention, the apparatus 1 for processing supercritical substrate may perform the drying process on the substrate S which has completed the cleaning process for cleaning the substrate. Accordingly, the apparatus 1 for processing supercritical substrate according to the present invention may dry the cleaning liquid applied to the substrate S in the cleaning process through the drying process. Here, the cleaning liquid may be an anti-drying liquid. The anti-drying liquid may be isopropyl alcohol (IPA). The apparatus 1 for processing supercritical substrate according to the present invention may dry the anti-drying liquid applied to the substrate by spraying a drying fluid. The drying fluid may be a supercritical fluid. The apparatus 1 for processing supercritical substrate according to the present invention may dry the anti-drying liquid by spraying the drying fluid in a supercritical state onto the substrate. In apparatus 1 for processing supercritical substrate according to the present invention, the inside of the chamber 2 needs to be maintained at high temperature and high pressure to maintain the drying fluid in a supercritical state.

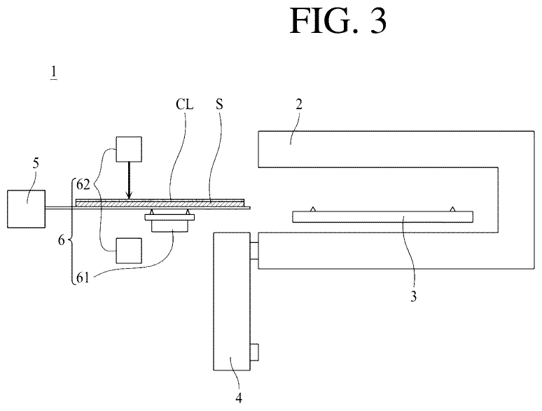

Referring to FIG. 2 and FIG. 3, the apparatus 1 for processing supercritical substrate according to the present invention may include a chamber 2 having a processing space; a substrate supporting unit 3 for supporting a substrate S; an opening/closing unit 4 for opening or closing the processing space; a loading/unloading unit 5 for loading a substrate S onto or unloading the substrate S from the substrate supporting unit 3; a detection unit 6 for detecting the loading/unloading unit 5 or the substrate S; and a control unit 7 for controlling the opening/closing unit 4. In this case, the control unit 7 may control the driving of the opening/closing unit 4 as the detection unit 6 detects the loading/unloading unit 5 or the substrate S.

Accordingly, the apparatus 1 for processing supercritical substrate according to the present invention may implement the following effects.

The apparatus 1 for processing supercritical substrate according to the present invention may be implemented such that the control unit 7 drives the opening/closing unit 4 through the result of the detection of the loading/unloading unit 5 or the substrate S by the detection unit 6. Accordingly, the apparatus 1 for processing supercritical substrate according to the present invention detects that the loading/unloading unit 5 or the substrate S is driven, and thus may prevent the loading/unloading unit 5 or the substrate S and the opening/closing unit 4 from being driven simultaneously. Accordingly, the apparatus 1 for processing supercritical substrate according to the present invention may prevent the loading/unloading unit 5 or the substrate S from colliding with each other as the opening/closing unit 4 and the loading/unloading unit 5 or the substrate S are driven simultaneously, thereby preventing the loading/unloading unit 5 or the substrate S from being damaged.

Hereinafter, the chamber 2, the substrate supporting unit 3, the opening/closing unit 4, the loading/unloading unit 5, the detection unit 6, and the control unit 7 will be described in detail with reference to the attached drawings.

Referring to FIG. 2 the apparatus 1 for processing supercritical substrate according to the present invention may include the chamber 2.

The chamber 2 is provided with a processing space. The chamber 2 may perform a drying process of drying the substrate S in the processing space. The processing space may be disposed inside the chamber 2. The processing space may be disposed as an empty space disposed inside the chamber 2. The chamber 2 may include an exhausting part (not shown) for discharging the drying fluid from the processing space.

Referring to FIG. 2, the apparatus 1 for processing supercritical substrate according to the present invention may include a substrate supporting unit 3.

The substrate supporting unit 3 supports the substrate S. The substrate support unit 3 may be disposed in the processing space. The processing process may be performed in a state in which the substrate supporting unit 3 supports the substrate S. The substrate S may be mounted on an upper side of the substrate supporting unit 3. In this case, the injection part (not shown) may inject the drying fluid toward the substrate S. The injection part may be disposed to face the substrate S from the upper side of the substrate supporting unit 3.

Referring to FIG. 2, the apparatus 1 for processing supercritical substrate according to the present invention may include an opening/closing unit 4.

The opening/closing unit 4 opens or closes the processing space. The opening/closing unit 4 may be detachably coupled to the chamber 2. The opening/closing unit 4 may be moved to a position that opens the processing space when the substrate S is carried into the substrate supporting unit 3 or taken out from the substrate supporting unit 3. Conversely, the opening/closing unit 4 may be moved to a position that closes the processing space when the drying process is performed. Driving of the opening/closing unit 4 may be controlled by the control unit 7.

Referring to FIGS. 2 to 6, the apparatus 1 for processing supercritical substrate according to the present invention may the loading/unloading unit 5.

The loading/unloading unit 5 is to carry the substrate S onto the substrate supporting unit 3 or to carry out the substrate S from the substrate supporting unit 3. The loading/unloading unit 5 may be moved to enter the processing space. Conversely, the loading/unloading unit 5 may be moved to retreat to the opposite side of the processing space. When the substrate S is carried into the chamber 2, the loading/unloading unit 5 may be moved from the open portion of the chamber 2 to the processing space to transfer the substrate S to the substrate supporting unit 3. When the substrate S is carried out of the chamber 2, the loading/unloading unit 5 may receive the substrate S from the substrate supporting part 3 and then may be moved to the open portion of the chamber 2 in the processing space.

Referring to FIGS. 2 to 6, the apparatus 1 for processing supercritical substrate according to the present invention may include a detection unit 6 and a control unit 7. Although the control unit 7 is not illustrated in FIGS. 3 to 6, the control unit 7 may be provided to control the movement of the opening/closing unit 4.

The detection unit 6 detects the loading/unloading unit 5 or the substrate S. The detection unit 6 can detect the loading/unloading unit 5. In addition, the detection unit 6 can detect the weight of the cleaning solution CL applied to the substrate S. The detection unit 6 can detect the weight of the loading/unloading unit 5 or the cleaning solution CL before the loading/unloading unit 5 loads the substrate S into the processing space. In this case, the control unit 7 can limit the operation of the opening/closing unit 4 so that the opening/closing unit 4 maintains the processing space in an open state while the detection unit 6 detects the weight of the loading/unloading unit 5 or the cleaning solution CL. Accordingly, the apparatus 1 for processing supercritical substrate according to the present invention can prevent the opening/closing unit 4 from colliding with the loading/unloading unit 5 or the substrate S by blocking the operation of the opening/closing unit 4 while the detection unit 6 detects the weight of the loading/unloading unit 5 or the cleaning liquid CL. Meanwhile, the detection unit 6 may be arranged on the outside of the chamber 2.

The control unit 7 (shown in FIG. 2) controls the operation of the opening/closing unit 4. The control unit 7 can control the operation of the opening/closing unit 4 when the detection unit 6 detects the loading/unloading unit 5 or the substrate S. The control unit 7 can control the opening/closing unit 4 to limit the operation of the opening/closing unit 4. The control unit 7 can control the opening/closing unit 4 according to the detection result detected by the detection unit 6.

Here, the detection unit 6 and the control unit 7 can operate as follows to prevent the loading/unloading unit 5 and the opening/closing unit 4 from colliding. In this case, the detection unit 6 can include a first detection member 61 and a second detection member 62 to detect the weight of the loading/unloading unit 5 or the cleaning solution CL.

The first detection member 61 detects the weight of the cleaning solution CL. As illustrated in FIG. 3, the first detection member 61 can detect the weight of the cleaning solution CL applied to the substrate S before the substrate S is transported into the processing space by the loading/unloading unit 5. In this case, the control unit 7 can control the opening/closing unit 4 not to operate when the weight detected by the first detection member 61 exceeds a preset weight. For example, if the weight detected by the first detection element 61 exceeds a preset weight of 100 gram, the control unit 7 can determine that the substrate S applied with the cleaning solution CL has not yet been introduced into the chamber 2, and thus control the opening/closing unit 4 to not operate. Accordingly, the apparatus 1 for processing supercritical substrate according to the present invention can prevent the substrate S and the opening/closing unit 4 from colliding by blocking the opening/closing unit 4 from operating before the substrate S is introduced into the chamber 2.

The second detection member 62 detects the loading/unloading unit 5. The second detection member 62 can detect whether the loading/unloading unit 5 exists. As illustrated in FIG. 3, the second detection member 62 can detect the loading/unloading unit 5 before the loading/unloading unit 5 loads the substrate S into the processing space. In this case, the control member 7 can control the opening/closing unit 4 not to be operated when the loading/unloading unit 5 is detected by the second detection member 62. Accordingly, apparatus 1 for processing supercritical substrate according to the present invention can prevent the loading/unloading unit 5 and the opening/closing unit 4 from colliding by blocking the operation of the opening/closing unit 4 before the loading/unloading unit 5 loads the substrate S into the processing space. If the loading/unloading unit 5 is detected by the second detection member 62, the control unit 7 can determine that the loading/unloading unit 5 is positioned at the position before the substrate S is loaded into the processing space. If the loading/unloading unit 5 is not detected by the second detection member 62, the control unit 7 can determine that the loading/unloading unit 5 is not positioned at the position before the substrate S is loaded into the processing space. Meanwhile, the detection member 6 can be implemented as an optical sensor.

Referring to FIG. 3, the apparatus 1 for processing supercritical substrate according to the present invention can be implemented so that the first detection member 61 detects the weight of the cleaning solution CL and the second detection member 62 detects the loading/unloading member 5 at the same time before the loading/unloading member 5 supporting the substrate S is loaded into the processing space. Accordingly, the apparatus 1 for processing supercritical substrate according to the present invention can prevent the opening/closing member 4 from malfunctioning by doubly detecting the substrate S and the loading/unloading member 5 through the first detection member 61 and the second detection member 62. Accordingly, the apparatus 1 for processing supercritical substrate according to the present invention can prevent the opening/closing unit 4 from colliding with the opening/closing unit 5 by blocking the opening/closing unit 4 from operating before the loading/unloading unit 5 loads the substrate S into the processing space.

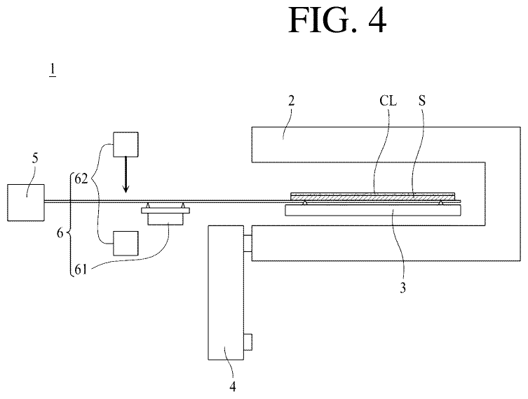

Referring to FIG. 4, the loading/unloading unit 5 can enter the processing space while supporting the substrate S. In this case, the second detection member 62 can be kept turned on to detect the loading/unloading unit 5. Accordingly, the apparatus 1 for processing supercritical substrate according to the present invention can be implemented so that the second detection member 62 detects the loading/unloading unit 5 while the loading/unloading unit 5 load the substrate into the processing space. Accordingly, the apparatus 1 for processing supercritical substrate according to the present invention can prevent the opening/closing unit 4 and the loading/unloading unit 5 from colliding during the loading/unloading unit 5 load the substrate into the processing space by means of the second detection member 62. In addition, the second detection member 62 may be maintained in a turned-on state to detect the load/unload unit 5 when the load/unload unit 5 is withdrawn from the processing space after loading the substrate S into the processing space. Accordingly, the apparatus 1 for processing supercritical substrate according to the present invention may be implemented so that the second detection member 62 detects the load/unload unit 5 during the process in which the load/unload unit 5 loads the substrate S and is withdrawn. Accordingly, the apparatus 1 for processing supercritical substrate according to the present invention can prevent the opening/closing unit 4 and the load/unload unit 5 from colliding during the process in which the load/unload unit 5 loads the substrate S and is withdrawn by means of the second detection member 62.

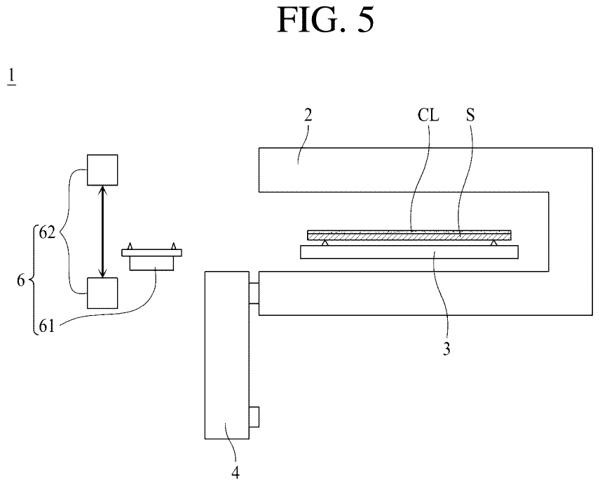

Referring to FIG. 5, the load/unload unit 5 may be withdrawn from the processing space after loading the substrate S onto the substrate supporting unit 3. In this case, since the loading/unloading unit 5 has been moved from the position for loading the substrate S to a different position, the first detection member 61 and the second detection member 62 can be maintained in a turned-off state. Since there is no detection result from the first detection member 61 and the second detection member 62, the control unit 7 of FIG. 2 can send a signal to the opening/closing unit 4 to drive the opening/closing unit 4.

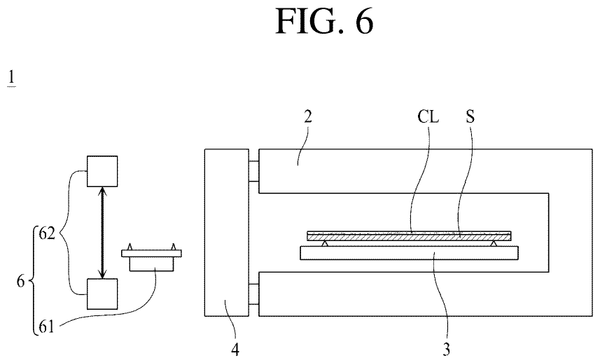

Referring to FIG. 6, the opening/closing unit 4 can be moved from a position for opening the processing space to a position for closing the processing space by receiving a signal from the control unit 7 of FIG. 2. In this case, with the loading/unloading unit 5 removed, there is no room for the loading/unloading unit 5 and the opening/closing unit 4 to collide with each other.

In addition to the above-mentioned effects, other features and advantages of the present application may be described below, or may be clearly understood by those of ordinary skill in the art to which the present application belongs from such techniques and descriptions.

In addition to the above-mentioned effects, other features and advantages of the present invention may be described below, or may be clearly understood by those of ordinary skill in the art to which the present invention belongs from such techniques and descriptions.

In addition to the above-mentioned effects, other features and advantages of the present invention will be described below or clearly understood by those of ordinary skill in the art to which the present invention belongs from such technology and description.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. An apparatus for processing supercritical substrate comprising:
a chamber having a processing space;
a substrate supporting unit for supporting a substrate;
an opening/closing unit for opening or closing the processing space;
a loading/unloading unit for loading a substrate into or unloading the substrate from the substrate supporting unit;
a detection unit for detecting the loading/unloading unit or the substrate; and
a control unit for controlling the opening/closing unit,
wherein the control unit controls the operation of the opening/closing unit in response to the detection unit detecting the loading/unloading unit or the substrate.

2. The apparatus for processing supercritical substrate according to claim 1, wherein the detection unit detects a weight of a cleaning solution applied to the loading/unloading unit or the substrate before the loading/unloading unit loads the substrate, and the control unit restricts the operation of the opening/closing unit so that the processing space remains open while the detection unit detects the weight of the loading/unloading unit or the cleaning solution.

3. The apparatus for processing supercritical substrate according to claim 1, wherein the detection unit includes a first detection member that detects the weight of the cleaning solution applied to the substrate, and the control unit controls the opening/closing unit not to be driven when the weight detected by the first detection member exceeds a preset weight.

4. The apparatus for processing supercritical substrate according to claim 1, wherein the detection unit includes a second detection member that detects the loading/unloading unit, and the control unit controls the opening/closing unit not to be driven when the loading/unloading unit is detected by the second detection member.

5. The apparatus for processing supercritical substrate according to claim 1, wherein the detection unit includes a first detection member that detects the weight of the cleaning solution applied to the substrate, and a second detection member that detects the loading/unloading unit, and wherein the first detection member detects the weight of the cleaning solution and the second detection member detects the loading/unloading unit at the same time, before the substrate is brought into a processing space with the loading/unloading unit supporting the substrate.

6. The apparatus for processing supercritical substrate according to claim 4, wherein, when the loading/unloading unit enters the processing space with supporting the substrate, the second detection member remains in turned-on state to detect the loading/unloading unit.

7. The apparatus for processing supercritical substrate according to claim 4, wherein, when the loading/unloading unit is retracting from the processing space after loading the substrate, the second detection member remains in turned-on state to detect the loading/unloading unit.

8. The apparatus for processing supercritical substrate according to claim 5, wherein, when the loading/unloading unit is retracted from the processing space after loading the substrate onto the substrate supporting unit, the first detection member and the second detection member remains in turned-off state.
